(19) United States
(12) Patent Application Publication
(10) Pub. No.: US 2026/0121645 A1
(43) Pub. Date: Apr. 30, 2026

(54) CURRENT REFERENCE GENERATOR AND ASSOCIATED METHOD

(71) Applicant: STMicroelectronics International N.V., Geneva (CH)

(72) Inventors: Yash KUMAR, Greater Noida (IN); Nitin JAIN, Greater Noida (IN); Kallol CHATTERJEE, KOLKATA (IN)

(21) Appl. No.: 18/949,007

(22) Filed: Nov. 15, 2024

Related U.S. Application Data
(60) Provisional application No. 63/603,954, filed on Nov. 29, 2023.

(51) Int. Cl. H03L 7/099; H03L 7/089

(52) U.S. Cl. CPC H03L 7/0992; H03L 7/0895

(57) ABSTRACT

In accordance with various embodiments of the present disclosure, a circuit to provide a reference current to a device having a first current controlled oscillator (CCO) is provided. In some embodiments, the circuit comprises a reference circuit and a feedback loop circuit. The feedback loop circuit comprises a differential circuit that receives an input voltage from the reference circuit and provides an output current, a second CCO that receives the output current from the differential circuit and produces an output frequency in response, a divider circuit to divide the output frequency into a feedback frequency, and a feedback switched capacitor resistor circuit providing a feedback voltage to the differential circuit based on the feedback frequency. The second CCO has substantially matching performance to the first CCO. The differential circuit adjusts its output current based on a difference between the input voltage and the feedback voltage.

### CROSS-REFERENCE TO RELATED APPLICATIONS

This application claims priority to and the benefit of U.S. Provisional Patent Application Ser. No. 63/603,954, filed Nov. 29, 2023, and titled “CURRENT REFERENCE GENERATOR AND ASSOCIATED METHOD,” which is incorporated herein by reference in its entirety.

### FIELD OF THE INVENTION

Example embodiments of the present disclosure relate generally to digitally controlled oscillators and, more particularly, to circuits, integrated circuits, methods, systems, and apparatuses for providing a reference current to a digitally controlled oscillator.

### BACKGROUND

In many applications, such as Phase Locked Loops, it is necessary to generate a frequency. This is often done with a Digitally Controlled Oscillator (DCO) or a Voltage Controlled Oscillator (VCO). A DCO takes a digital input and converts it into frequency and a VCO takes a voltage input and converts it into frequency.

A DCO comprises essentially a Digital-to-Analog Converter (DAC) and a Current Controlled Oscillator (CCO). To generate a frequency, a DCO needs a current reference. The reference current requirement of the CCO in the DCO to generate the same frequency changes as the process, voltage, and/or temperature (PVT) of the CCO changes. That is, as PVT changes occur, different ranges of reference currents are required to provide the same frequency.

A conventional current reference generates a current that is independent of the CCO current requirement. Depending on the CCO requirement, the conventional current reference may not provide the required current for the CCO to produce the desired frequency. As such, the conventional DAC will make the necessary changes to the input to the CCO. However, this requires and larger, more complex DAC which has a larger footprint and requires more complex code to control.

Applicant has identified many technical challenges and difficulties associated with providing a reference current to a digitally controlled oscillator. Through applied effort, ingenuity, and innovation, Applicant has solved problems related to providing a reference current to a digitally controlled oscillator by developing solutions embodied in the present disclosure, which are described in detail below.

### BRIEF SUMMARY

Various embodiments described herein related to circuits, integrated circuits, methods, apparatuses, and systems for providing provide a reference current to a digitally controlled oscillator (DCO) or a voltage controlled oscillator (VCO).

In accordance with various embodiments of the present disclosure, a circuit to provide a reference current to a device having a first current controlled oscillator (CCO) is provided. In some embodiments, the circuit comprises a reference circuit providing an input voltage or an input current based on a reference frequency and a feedback loop circuit. The feedback loop circuit comprises a differential circuit having a first input that receives the input voltage or the input current from the reference circuit and provides an output current, a second CCO that receives the output current from the differential circuit and produces an output frequency in response, the second CCO adapted to have substantially matching performance to the first CCO, a divider circuit to divide the output frequency into a feedback frequency, and a feedback switched capacitor resistor circuit providing a feedback voltage or a feedback current to a second input of the differential circuit based on the feedback frequency. The differential circuit adjusts its output current based on a difference between the input voltage and the feedback voltage or between the input current and the feedback current. The differential circuit is adapted to provide the output current to the device having the first CCO as the reference current. The feedback frequency is adapted to be substantially equal to a divided version of an output frequency of the device having the first CCO due to the second CCO having substantially matching performance to the first CCO.

In some embodiments, the device having the first CCO comprises a digitally controlled oscillator (DCO) or a voltage controlled oscillator (VCO).

In some embodiments, the divider circuit is selected such that the feedback frequency equals the reference frequency when the input voltage equals the feedback voltage or the input current equals the feedback current.

In some embodiments, the second CCO is adapted to have substantially a same structure as the first CCO.

In some embodiments, the differential circuit comprises a differential amplifier and a voltage-to-current converter connected to an output of the differential amplifier.

In some embodiments, the reference circuit comprises a reference switched capacitor resistor circuit.

In some embodiments, the input voltage provided to the first input of the differential circuit is a reference voltage, the reference circuit further comprises a differential amplifier and a voltage-to-current converter connected to an output of the differential amplifier, the reference voltage is provided to a first input of the differential amplifier, the reference frequency and a first current from the voltage-to-current converter are input to the reference switched capacitor resistor circuit to generate a first voltage provided to a second input of the differential amplifier, the first current from the voltage-to-current converter is mirrored to the feedback loop circuit to provide a second current, and the second current and the feedback frequency are input to the feedback switched capacitor resistor circuit to generate the feedback voltage provided to the differential circuit.

In some embodiments, the reference frequency and a first current are input to the reference switched capacitor resistor circuit to generate the input voltage provided to the first input of the differential circuit, and the feedback frequency and a second current equal to the first current are input to the feedback switched capacitor resistor circuit to generate the feedback voltage provided to the second input of the differential circuit.

In some embodiments, the reference circuit further comprises a first differential amplifier and a first voltage-to-current converter connected to an output of the first differential amplifier, a reference voltage is provided to a first input of the first differential amplifier, the reference frequency and a first current from the first voltage-to-current converter are input to the reference switched capacitor resistor circuit to generate a first voltage provided to a second input of the first differential amplifier, the first current from the first voltage-to-current converter is the input current provided to the first input of the differential circuit, the feedback loop circuit further comprises a second differential amplifier and a second voltage-to-current converter connected to an output of the second differential amplifier, the reference voltage is provided to a first input of the second differential amplifier, a second current from the second voltage-to-current converter is input to the feedback switched capacitor resistor circuit to generate a second voltage provided to a second input of the second differential amplifier, and the second current from the second voltage-to-current converter is the feedback current to the second input of the differential circuit.

In accordance with various embodiments of the present disclosure, a method of providing a reference current to a device having a first current controlled oscillator (CCO) is provided. In some embodiments, the method comprises providing, by a reference circuit to a first input of a differential circuit of a feedback loop circuit, an input voltage or an input current based on a reference frequency; providing, by the differential circuit, an output current; receiving, by a second CCO, the output current from the differential circuit, the second CCO adapted to have substantially matching performance to the first CCO; producing, by the second CCO, an output frequency in response to the received output current; dividing, by a divider circuit, the output frequency into a feedback frequency; providing, by a feedback switched capacitor resistor circuit, a feedback voltage or a feedback current to a second input of the differential circuit based on the feedback frequency; adjusting, by the differential circuit, its output current based on a difference between the input voltage and the feedback voltage or between the input current and the feedback current; and providing, by the differential circuit, the output current to the device having the first CCO as the reference current. The feedback frequency is adapted to be substantially equal to a divided version of an output frequency of the device having the first CCO due to the second CCO having substantially matching performance to the first CCO.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 illustrates a block diagram of an example circuit for providing a reference current to a digitally controlled oscillator, in accordance with some embodiments of the present disclosure;

FIGS. 2 and 3 illustrate block diagrams of example circuits for providing a reference current to a digitally controlled oscillator, in accordance with alternative embodiments of the present disclosure; and

FIG. 4 is an example flow diagram illustrating an example method for providing a reference current to a digitally controlled oscillator, in accordance with an example embodiment of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing example circuits, integrated circuits, methods, devices, and systems for providing a current reference for a DCO that tracks PVT variations of a CCO. In various embodiments, this methodology is helpful in, for example, a phase locked loop (PLL) in which a current reference is needed to generate a desired frequency using a DCO or a voltage controlled oscillator (VCO). In analog PLLs, the current reference is used for the charge pump current, which the loop filter converts into a voltage input for the VCO. In digital PLLs, the current reference is used as a reference for the digital-to-analog converter (DAC).

Various embodiments of the present disclosure provide a circuit and method to generate a current reference for a DCO or VCO that tracks the PVT variation of the CCO. In various embodiments, a feedback loop uses a replica or duplicate of the CCO of the DCO/VCO to anticipate potential changes in the output of the CCO of the DCO/VCO due to PVT changes.

In various embodiments, a reference circuit provides either an input voltage or an input current to a differential circuit of a feedback loop circuit having what may be termed a replica CCO. In various embodiments, the replica CCO has substantially matching performance to the CCO of the DCO/VCO and is therefore affected by any PVT changes in substantially the same manner. In various embodiments, the replica CCO has substantially the same structure and components as the CCO of the DCO/VCO.

In various embodiments, the replica CCO receives an output current from the differential circuit and produces an output frequency. In various embodiments, the output frequency is divided and provided to a switched capacitor resistor circuit which, in turn, provides either a feedback voltage or a feedback current to the differential circuit. In various embodiments, the differential circuit adjusts its output current based on a difference between the input voltage and the feedback voltage or between the input current and the feedback current. Thus, the output current from the differential circuit adjusts in response to PVT changes to the replica CCO. In various embodiments, the output current from the differential circuit is provided as a reference current to a DCO of a digital PLL to enable the desired frequency output. Since the replica CCO is affected by any PVT changes in substantially the same manner as the CCO of the DCO/VCO, the provided reference current compensates (at least partially) for the PVT changes.

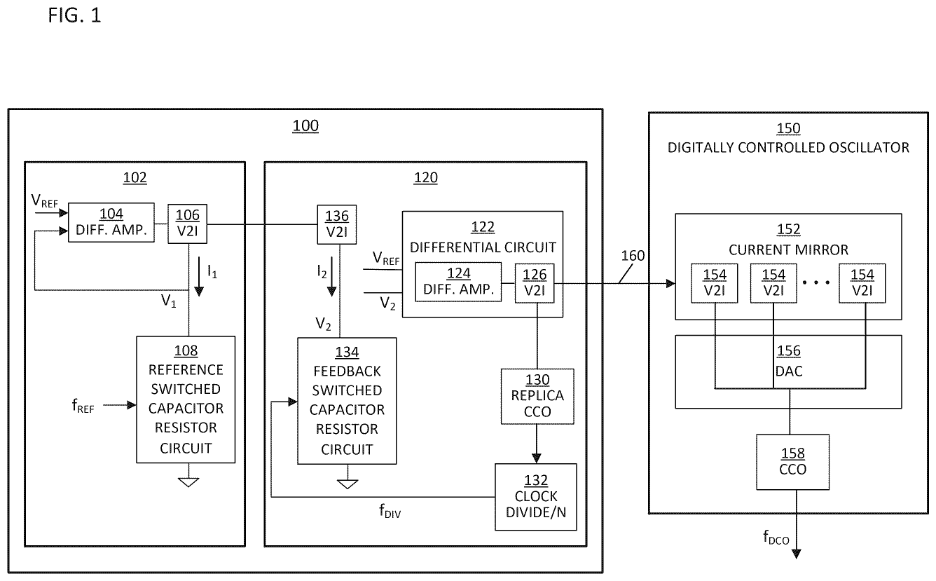

FIG. 1 illustrates a block diagram of an example circuit providing a current reference for a DCO that tracks the PVT variation of the DCO's CCO using a replica CCO, as described herein. While various embodiments of the present disclosure provide a circuit and method to generate a current reference for either a DCO or a VCO, for simplicity, embodiments of the present disclosure will be described herein in relation to generating a current reference for a DCO.

As seen in FIG. 1, an example circuit 100 comprises a reference circuit portion 102 and a feedback loop circuit portion 120. The reference circuit portion 102 provides a voltage (or current in alternative embodiments described below) to the feedback loop circuit portion 120. In the illustrated embodiment, the reference circuit portion 102 comprises a differential amplifier 104, a voltage-to-current (V2I) converter 106 connected to the output of the differential amplifier 104, and a switched capacitor resistor circuit 108 (herein termed a “reference switched capacitor resistor circuit” because of its location in the reference circuit) connected to the output of the V2I converter 106. The reference switched capacitor resistor circuit 108 has a capacitance of C_{SW1}.

In the illustrated embodiment, a reference voltage V_{REF} is provided to a first input of the differential amplifier 104. In some embodiments, Vref comes from a resistor divider with supply, or can be a BangGap voltage. In the illustrated embodiment, a reference frequency f_{REF} (which may also be termed an input frequency) is input to the reference switched capacitor resistor circuit 108. In various embodiments, the input frequency f_{REF} is the PLL input frequency. In the illustrated embodiment, the current output I₁ from the V2I converter 106 is also input to the reference switched capacitor resistor circuit 108. The resistance of a switched capacitor resistor is 1/fC, so the resistance of the reference switched capacitor resistor circuit 108 is 1/ (f_{REF}×C_{SW1}). With an input current of I₁, the voltage V₁ across the reference switched capacitor resistor circuit 108 is equal to I₁/(f_{REF}×C_{SW1}). In the illustrated embodiment, the voltage V₁ is provided to a second input of the differential amplifier 104 as feedback to help maintain the current I₁ at a steady level. In the illustrated embodiment, the current I₁ is also mirrored to the feedback loop circuit portion 120 via a voltage-to-current (V2I) converter 136.

In the illustrated embodiment, the feedback loop circuit portion 120 comprises the V2I converter 136, a differential circuit portion 122, a replica CCO 130, a divider circuit portion 132, and a switched capacitor resistor circuit 134 (herein termed a “feedback switched capacitor resistor circuit” because of its location in the feedback loop circuit). In the illustrated embodiment, the differential circuit portion 122 comprises a differential amplifier 124 and a V2I converter 126. As described above, the replica CCO 130 has substantially matching performance to the CCO 158 of the DCO 150 and is therefore affected by any PVT changes in substantially the same manner.

In the illustrated embodiment, the reference voltage V_{REF} is provided to a first input of the differential amplifier 124. In the illustrated embodiment, the current output from the V2I converter 126 is input to the replica CCO 130 which produces an output frequency. In the illustrated embodiment, the output frequency is divided by the divider circuit portion 132. In various embodiments, the divider circuit portion 132 divides the output frequency from the replica CCO 130 such that the divided frequency f_{DIV} is equal to the reference frequency f_{REF} when the feedback loop is working and compensating for any PVT changes (as described below). In the illustrated embodiment, the divided frequency f_{DIV} is provided to the feedback switched capacitor resistor circuit 134. In the illustrated embodiment, the current output from the V2I converter 126 which is input to the replica CCO 130 is also output as a reference current 160 to the DCO 150 (the DCO 150 is described further below).

The feedback switched capacitor resistor circuit 134 has a capacitance of C_{SW2}. The resistance of a switched capacitor resistor is 1/fC, so the resistance of the feedback switched capacitor resistor circuit 134 is 1/(f_{REF}×C_{SW2}). With an input current of I₂ from the V2I converter 136, the voltage V₂ across the feedback switched capacitor resistor circuit 134 is equal to 12/(f_{DIV}×C_{SW2}). In the illustrated embodiment, the voltage V₂ is provided to a second input of the differential amplifier 124 as feedback.

In various embodiments, the capacitance of the reference switched capacitor resistor circuit 108, C_{SW1}, is equal to the capacitance of the feedback switched capacitor resistor circuit 134, C_{SW2}. In various embodiments, the current I₁ provided to the reference switched capacitor resistor circuit 108 is the same as the current I₂ provided to the feedback switched capacitor resistor circuit 134 since I₁ comes from a feedback loop comprising differential amplifier 104 and I₂ is made equal to I₁. Since C_{SW1} is equal to C_{SW2} and I₁ is equal to I₂, then if the feedback loop circuit portion 120 successfully makes the voltage V₂ across the feedback switched capacitor resistor circuit 134 equal to the reference voltage V_{REF}, then the divided frequency f_{DIV} is equal to the reference frequency f_{REF}.

In various embodiments, if the output frequency of the replica CCO 130 changes due to PVT changes (which, as described above, would be substantially the same as PVT changes occurring in the CCO 158 of the DCO 150), the voltage V₂ across the feedback switched capacitor resistor circuit 134 will correspondingly change. In response, the differential amplifier 124 will compare these two voltages (V_{REF} and V₂) and try to make the voltage V₂ across the feedback switched capacitor resistor circuit 134 equal to the reference voltage V_{REF} by adjusting its output voltage to the V2I converter 126, which changes the current to the replica CCO 130 and therefore the output of the replica CCO 130. Since the current output from the V2I converter 126 which is input to the replica CCO 130 is also output as a reference current 160 to the DCO 150, the adjustments that the differential amplifier 124 will make to its output in response to PVT changes will also result in corresponding changes to the reference current 160 being provided to the DCO 150. In this regard, the circuit 100 compensates for some or all PVT changes occurring in the CCO 158 of the DCO 150.

In the illustrated embodiment, the DCO 150 comprises a current mirror 152 (which in turn comprises a plurality of V2I converters 154), a DAC 156, and the CCO 158. The DCO 150 outputs the desired frequency f_{DCO} based on the supplied reference current 160. The reference current 160 from the circuit 100 to the DCO 150 is mirrored via the current mirror 152 and provided to the DAC 156 which in turn provides the necessary signal to the CCO 158. Because the reference current 160 from the circuit 100 to the DCO 150 has been adjusted to correct for the PVT changes, the DAC 156 does not need to adjust the reference current (or only needs to make minor adjustments), so the DAC in this case can be much smaller and simpler.

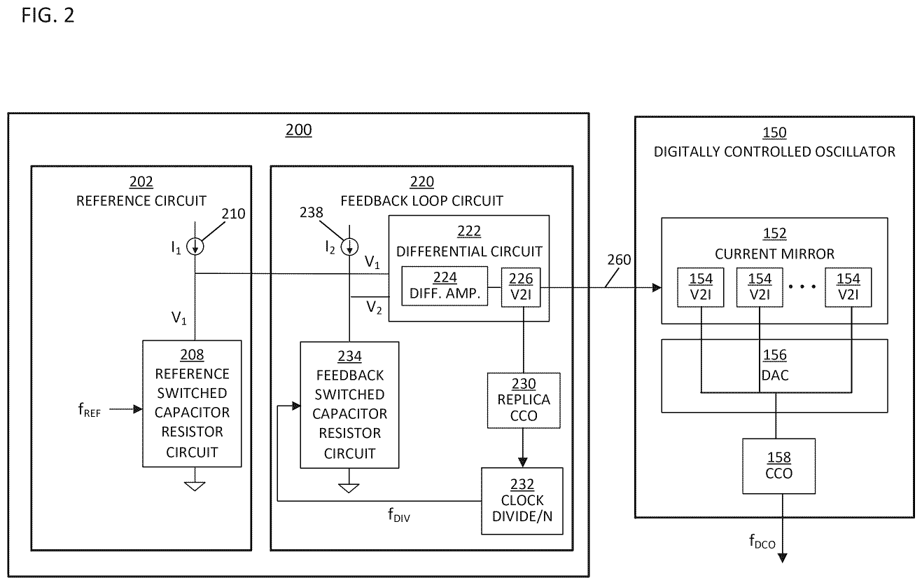

FIG. 2 illustrates a block diagram of an example circuit providing a current reference for a DCO that tracks the PVT variation of the DCO's CCO using a replica CCO, in accordance with alternative embodiments of the present disclosure. As seen in FIG. 2, an example circuit 200 comprises a reference circuit portion 202 and a feedback loop circuit portion 220. The reference circuit portion 202 provides a voltage V₁ as a reference voltage to the feedback loop circuit portion 220. In the illustrated embodiment, the reference circuit portion 202 comprises a current source 210 that outputs a current I₁ and a switched capacitor resistor circuit 208 (herein termed a “reference switched capacitor resistor circuit” because of its location in the reference circuit) connected to the current source 210. The reference switched capacitor resistor circuit 208 has a capacitance of C_{SW1}.

In the illustrated embodiment, a reference frequency f_{REF} (which may also be termed an input frequency) is input to the reference switched capacitor resistor circuit 208. In various embodiments, the input frequency f_{REF} is the external input frequency. In the illustrated embodiment, the current I₁ from the current source 210 is input to the reference switched capacitor resistor circuit 208. The resistance of a switched capacitor resistor is 1/fC, so the resistance of the reference switched capacitor resistor circuit 208 is 1/(f_{REF}×C_{SW1}). With an input current of I₁, the voltage V₁ across the reference switched capacitor resistor circuit 208 is equal to I₁/(f_{REF}×C_{SW1}). In the illustrated embodiment, the voltage V₁ is provided to a first input of a differential circuit portion 222 (described further below) of the feedback loop circuit portion 220.

In the illustrated embodiment, the feedback loop circuit portion 220 comprises a current source 238 that outputs a current I₂, a differential circuit portion 222, a replica CCO 230, a divider circuit portion 232, and a switched capacitor resistor circuit 234 (herein termed a “feedback switched capacitor resistor circuit” because of its location in the feedback loop circuit). In the illustrated embodiment, the differential circuit portion 222 comprises a differential amplifier 224 and a V2I converter 226. As described above, the replica CCO 230 has substantially matching performance to the CCO 158 of the DCO 150 and is therefore affected by any PVT changes in substantially the same manner.

In the illustrated embodiment, the voltage V₁ from the reference circuit portion 202 is provided to a first input of the differential amplifier 224. In the illustrated embodiment, the current output from the V2I converter 226 is input to the replica CCO 230 which produces an output frequency. In the illustrated embodiment, the output frequency is divided by the divider circuit portion 232. In various embodiments, the divider circuit portion 232 divides the output frequency from the replica CCO 230 such that the divided frequency f_{DIV} is equal to the reference frequency f_{REF} when the feedback loop is working and compensating for any PVT changes (as described below). In the illustrated embodiment, the divided frequency f_{DIV} is provided to the feedback switched capacitor resistor circuit 234. In the illustrated embodiment, the current output from the V2I converter 226 which is input to the replica CCO 230 is also output as a reference current 260 to the DCO 150 (the DCO 150 is described further above).

The feedback switched capacitor resistor circuit 234 has a capacitance of C_{SW2}. The resistance of a switched capacitor resistor is 1/fC, so the resistance of the feedback switched capacitor resistor circuit 234 is 1/(f_{REF}×C_{SW2}). With an input current of I₂ from the current source 238, the voltage V₂ across the feedback switched capacitor resistor circuit 234 is equal to 12/(f_{DIV}×C_{SW2}). In the illustrated embodiment, the voltage V₂ is provided to a second input of the differential amplifier 224 as feedback.

In various embodiments, the capacitance of the reference switched capacitor resistor circuit 208, C_{SW1}, is equal to the capacitance of the feedback switched capacitor resistor circuit 234, C_{SW2}. In various embodiments, the current I₁ provided to the reference switched capacitor resistor circuit 208 is the same as the current I₂ provided to the feedback switched capacitor resistor circuit 234. Since C_{SW1} is equal to C_{SW2} and I₁ is equal to I₂, then if the feedback loop circuit portion 220 successfully makes the voltage V₂ across the feedback switched capacitor resistor circuit 234 equal to the voltage V₁ from the reference circuit portion 202, then the divided frequency f_{DIV} is equal to the reference frequency f_{REF}.

In various embodiments, if the output frequency of the replica CCO 230 changes due to PVT changes (which, as described above, would be substantially the same as PVT changes occurring in the CCO 158 of the DCO 150), the voltage V₂ across the feedback switched capacitor resistor circuit 234 will correspondingly change. In response, the differential amplifier 224 will compare these two voltages (V₁ and V₂) and try to make the voltage V₂ across the feedback switched capacitor resistor circuit 234 equal to the voltage V₁ from the reference circuit portion 202 by adjusting its output voltage to the V2I converter 226, which changes the current to the replica CCO 230 and therefore the output of the replica CCO 230. Since the current output from the V2I converter 226 which is input to the replica CCO 230 is also output as a reference current 260 to the DCO 150, the adjustments that the differential amplifier 224 will make to its output in response to PVT changes will also result in corresponding changes to the reference current 260 being provided to the DCO 150. In this regard, the circuit 200 compensates for some or all PVT changes occurring in the CCO 158 of the DCO 150. Because the reference current 260 from the circuit 200 to the DCO 150 has been adjusted to correct for the PVT changes, the DAC 156 does not need to adjust the reference current (or only needs to make minor adjustments), so the DAC 156 in this case can be much smaller and simpler.

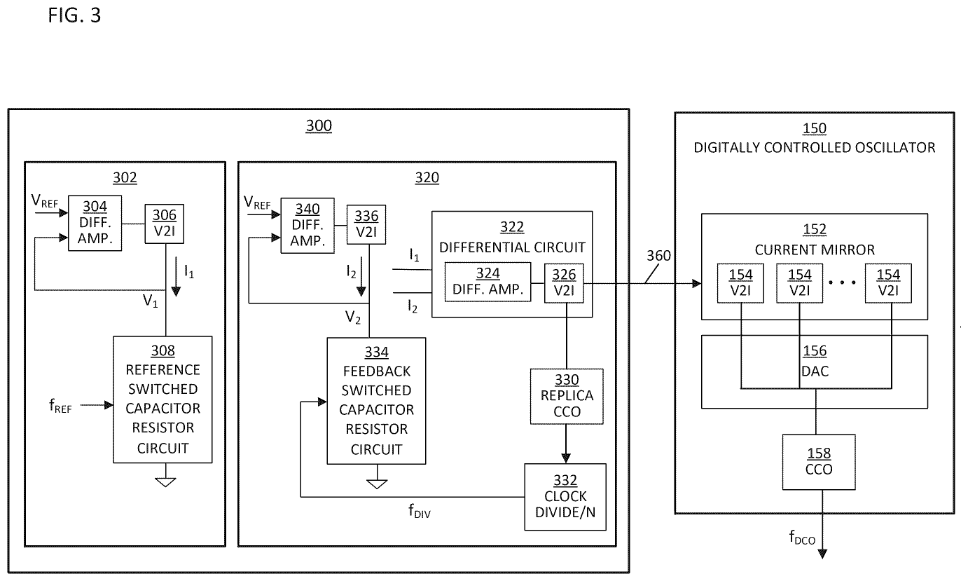

FIG. 3 illustrates a block diagram of an example circuit providing a current reference for a DCO that tracks the PVT variation of the DCO's CCO using a replica CCO, in accordance with alternative embodiments of the present disclosure. As seen in FIG. 3, an example circuit 300 comprises a reference circuit portion 302 and a feedback loop circuit portion 320. The reference circuit portion 302 provides a current to the feedback loop circuit portion 320. In the illustrated embodiment, the reference circuit portion 302 comprises a differential amplifier 304, a voltage-to-current (V2I) converter 306 connected to the output of the differential amplifier 304, and a switched capacitor resistor circuit 308 (herein termed a “reference switched capacitor resistor circuit” because of its location in the reference circuit) connected to the output of the V2I converter 306. The reference switched capacitor resistor circuit 308 has a capacitance of C_{SW1}.

In the illustrated embodiment, a reference voltage V_{REF} is provided to a first input of the differential amplifier 304. In some embodiments, Vref comes from a resistor divider with supply, or can be a BangGap voltage. In the illustrated embodiment, a reference frequency f_{REF} (which may also be termed an input frequency) is input to the reference switched capacitor resistor circuit 308. In various embodiments, the input frequency f_{REF} is the external input frequency. In the illustrated embodiment, the current output I₁ from the V2I converter 306 is also input to the reference switched capacitor resistor circuit 308. The resistance of a switched capacitor resistor is 1/fC, so the resistance of the reference switched capacitor resistor circuit 308 is 1/(f_{REF}×C_{SW1}). With an input current of I₁, the voltage V₁ across the reference switched capacitor resistor circuit 308 is equal to I₁ /(f_{REF}×C_{SW1}). In the illustrated embodiment, the voltage V₁ is provided to a second input of the differential amplifier 304 as feedback to help maintain the current I₁ at a steady level. In the illustrated embodiment, the current I₁ is provided to a first input of a differential circuit portion 322 (described further below) of the feedback loop circuit portion 320 as a reference current.

In the illustrated embodiment, the feedback loop circuit portion 320 comprises a differential amplifier 340, a voltage-to-current (V2I) converter 336 connected to the output of the differential amplifier 340, a differential circuit portion 322, a replica CCO 330, a divider circuit portion 332, and a switched capacitor resistor circuit 334 (herein termed a “feedback switched capacitor resistor circuit” because of its location in the feedback loop circuit). In the illustrated embodiment, the differential circuit portion 322 comprises a differential transresistance amplifier 324 and a V2I converter 326. As described above, the replica CCO 330 has substantially matching performance to the CCO 158 of the DCO 150 and is therefore affected by any PVT changes in substantially the same manner.

In the illustrated embodiment, the current In from the reference circuit portion 302 is provided as a reference current to a first input of the differential transresistance amplifier 324. In the illustrated embodiment, the current output from the V2I converter 326 is input to the replica CCO 330 which produces an output frequency. In the illustrated embodiment, the output frequency is divided by the divider circuit portion 332. In various embodiments, the divider circuit portion 332 divides the output frequency from the replica CCO 330 such that the divided frequency f_{DIV} is equal to the reference frequency f_{REF} when the feedback loop is working and compensating for any PVT changes (as described below). In the illustrated embodiment, the divided frequency f_{DIV} is provided to the feedback switched capacitor resistor circuit 334. In the illustrated embodiment, the current output from the V2I converter 326 which is input to the replica CCO 330 is also output as a reference current 360 to the DCO 150 (or to a charge pump of an analog PLL) (the DCO 150 is described further below).

In the illustrated embodiment, the current I₁ is provided to a first input of a differential circuit portion 322. In the illustrated embodiment, the current output I₂ from the V2I converter 336 is also input to the feedback switched capacitor resistor circuit 334. The feedback switched capacitor resistor circuit 334 has a capacitance of C_{SW2}. The resistance of a switched capacitor resistor is 1/fC, so the resistance of the feedback switched capacitor resistor circuit 334 is 1/(f_{REF}×C_{SW2}). With an input current of I₂, the voltage V₂ across the feedback switched capacitor resistor circuit 334 is equal to 12/(f_{REF}×C_{SW2}). In the illustrated embodiment, the voltage V₂ is provided to a second input of the differential amplifier 340 as feedback to help maintain the current I₂ at a steady level. In the illustrated embodiment, the current I₂ is provided to a second input of the differential transresistance amplifier 324 as feedback.

In various embodiments, the capacitance of the reference switched capacitor resistor circuit 308, C_{SW1}, is equal to the capacitance of the feedback switched capacitor resistor circuit 334, C_{SW2}. In various embodiments, if the output frequency of the replica CCO 330 changes due to PVT changes (which, as described above, would be substantially the same as PVT changes occurring in the CCO 158 of the DCO 150), the voltage V₂ across the feedback switched capacitor resistor circuit 334 will correspondingly change. In response, the differential amplifier 340 will compare these two voltages (V_{REF} and V₂) and try to make the voltage V₂ across the feedback switched capacitor resistor circuit 334 equal to the reference voltage V_{REF} by adjusting its output voltage to the V2I converter 336, which changes the current I₂ to the feedback switched capacitor resistor circuit 334 and to the second input of the differential transresistance amplifier 324. In response, the differential transresistance amplifier 324 will compare these two currents (I₁ and I₂) and try to make these two currents equal by adjusting its output voltage to the V2I converter 326, which changes the current to the replica CCO 330 and therefore the output of the replica CCO 330.

Since the current output from the V2I converter 326 which is input to the replica CCO 330 is also output as a reference current 360 to the DCO 150, the adjustments that the differential transresistance amplifier 324 will make to its output in response to PVT changes will also result in corresponding changes to the reference current 360 being provided to the DCO 150. In this regard, the circuit 300 compensates for some or all PVT changes occurring in the CCO 158 of the DCO 150. Because the reference current 360 from the circuit 300 to the DCO 150 has been adjusted to correct for the PVT changes, the DAC 156 does not need to adjust the reference current (or only needs to make minor adjustments), so the DAC 156 in this case can be much smaller and simpler.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitries both leverage use of the same processor(s), memory(ies), circuitry(ies), and/or the like to perform their associated functions such that duplicate hardware is not required for each set of circuitry.

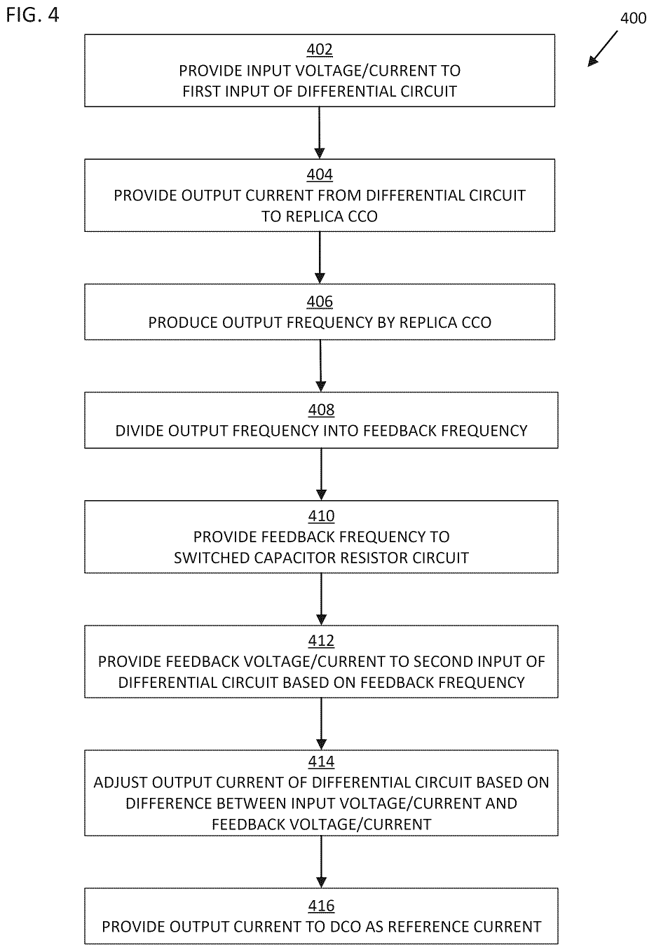

Reference will now be made to FIG. 4, which provides a flowchart illustrating example steps, processes, procedures, and/or operations in accordance with various embodiments of the present disclosure. Various methods described herein, including, for example, example methods as shown in FIG. 4, may provide various technical benefits and improvements. It is noted that each block of the flowchart, and combinations of blocks in the flowchart, may be implemented by various means such as hardware, firmware, circuitry and/or other devices associated with execution of software including one or more computer program instructions. For example, one or more of the procedures described in FIG. 4 may be embodied by computer program instructions, which may be stored by a non-transitory memory of an apparatus employing an embodiment of the present disclosure and executed by a processor in the apparatus. These computer program instructions may direct a computer or other programmable apparatus to function in a particular manner, such that the instructions stored in the computer-readable storage memory produce an article of manufacture, the execution of which implements the function specified in the flowchart block(s).

As described above and as will be appreciated based on this disclosure, embodiments of the present disclosure may be configured as methods, mobile devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

Having described example systems, apparatuses, computing environments, and user interfaces associated with embodiments of the present disclosure, example flowcharts including various operations performed by the circuits, apparatuses, systems, and/or devices described herein will now be discussed. It should be appreciated that each of the flowcharts depicts an example process that may be performed by one or more of the circuits, apparatuses, systems, and/or devices described herein, for example utilizing one or more of the components thereof. The blocks indicating operations of each process may be arranged in any of a number of ways, as depicted and described herein. In some such embodiments, one or more blocks of any of the processes described herein occur concurrently rather than sequentially. In some such embodiments, one or more blocks of any of the processes described herein occur in-between one or more blocks of another process, before one or more blocks of another process, and/or otherwise operates as a sub-process of a second process. Additionally or alternative, any of the processes may include some or all of the steps described and/or depicted, including one or more optional operational blocks in some embodiments. In regards to the below flowcharts, one or more of the depicted blocks may be optional in some, or all, embodiments of the disclosure. Optional blocks are depicted with broken (or “dashed”) lines. Similarly, it should be appreciated that one or more of the operations of each flowchart may be combinable, replaceable, re-ordered, and/or otherwise altered as described herein.

Referring now to FIG. 4, an example flow diagram illustrating an example method 400 for providing a reference current to a digitally controlled oscillator in accordance with some embodiments of the present disclosure is illustrated. In some embodiments, the example method 400 may be implemented by an example circuit described herein, including, but not limited to, the example circuit 100 described above in connection with FIG. 1.

In the example method shown in FIG. 4, the example method 400 starts at step/operation 402. At step/operation 402, one or more components of a circuit (such as, but not limited to, the reference circuit portion 102 of the circuit 100 described above in connection with FIG. 1) provides an input voltage or input current to a first input of a differential circuit (such as, but not limited to, the differential circuit portion 122 described above in connection with FIG. 1).

At step/operation 404, one or more components of a circuit (such as, but not limited to, the differential circuit portion 122 of the circuit 100 described above in connection with FIG. 1) provides an output current to a replica CCO (such as, but not limited to, the replica CCO 130 described above in connection with FIG. 1).

At step/operation 406, one or more components of a circuit (such as, but not limited to, the replica CCO 130 of the circuit 100 described above in connection with FIG. 1) produces an output frequency.

At step/operation 408, one or more components of a circuit (such as, but not limited to, the divider circuit portion 132 of the circuit 100 described above in connection with FIG. 1) divides the output frequency into a feedback frequency.

At step/operation 410, one or more components of a circuit (such as, but not limited to, the circuit 100 described above in connection with FIG. 1) provides the feedback frequency to a switched capacitor resistor circuit (such as, but not limited to, the feedback switched capacitor resistor circuit 134 of the circuit 100 described above in connection with FIG. 1).

At step/operation 412, one or more components of a circuit (such as, but not limited to, the feedback switched capacitor resistor circuit 134 of the circuit 100 described above in connection with FIG. 1) provides a feedback voltage or feedback current to a second input of a differential circuit (such as, but not limited to, the differential circuit portion 122 described above in connection with FIG. 1).

At step/operation 414, one or more components of a circuit (such as, but not limited to, the differential circuit portion 122 of the circuit 100 described above in connection with FIG. 1) adjusts its output based on a difference between its input voltage and feedback voltage or between its input current and feedback current.

At step/operation 416, one or more components of a circuit (such as, but not limited to, the differential circuit portion 122 of the circuit 100 described above in connection with FIG. 1) provides its output current as a reference current to a DCO (such as, but not limited to, the DCO 150 described above in connection with FIG. 1).

In some embodiments, the example method shown in FIG. 4 continuously repeats.

Although the description above and the figures relate primarily to providing a reference current to a DCO, embodiments of the present disclosure can also be used to provide a reference current to a VCO having a CCO. Such embodiments can be used to reduce the gain of the VCO in a charge pump PLL. One approach to a PLL that has been used is to have a charge pump and analog loop filter provide a control voltage to a VCO having a voltage-to-current converter and a CCO. In various embodiments of the invention, the replica CCO (such as replica CCO 130 of example circuit 100, replica CCO 230 of example circuit 200, or replica CCO 330 of example circuit 300) has substantially matching performance to the CCO of the VCO and the generated reference current (such as reference current 160 from example circuit 100, reference current 260 from example circuit 200, or reference current 360 from example circuit 300) is provided to a second voltage-to-current converter of the VCO and to the CCO of the VCO.

In various embodiments, the example circuit for providing a reference current to a DCO or a VCO can instead be used as an analog only frequency locked loop (FLL). In such embodiments, the output from the replica CCO (which in such embodiments is not a replica, because there is not another device with a CCO being replicated) is not only provided to a divider circuit portion (such as divider circuit portion 132 of example circuit 100, divider circuit portion 232 of example circuit 200, or divider circuit portion 332 of example circuit 300) but is also output from the example circuit to be used as an analog only FLL. This can function as an analog only FLL (albeit a somewhat crude FLL) because the output from the “replica” CCO is equal to N×f_{DIV} which is approximately equal to N×f_{REF}.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to fragmented wideband tympanometry techniques for true wireless stereo, however, one skilled in the art may recognize that such principles may be applied to any audio device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of integrated circuit which has one or more phase locked loops or frequency locked loops.

Within the appended claims, unless the specific term “means for” or “step for” is used within a given claim, it is not intended that the claim be interpreted under 35 U.S.C. 112, paragraph 6.

1. A circuit to provide a reference current to a device having a first current controlled oscillator (CCO), the circuit comprising:
a reference circuit providing an input voltage or an input current based on a reference frequency; and
a feedback loop circuit comprising:
a differential circuit having a first input that receives the input voltage or the input current from the reference circuit and provides an output current;
a second CCO that receives the output current from the differential circuit and produces an output frequency in response, the second CCO adapted to have substantially matching performance to the first CCO;
a divider circuit to divide the output frequency into a feedback frequency; and
a feedback switched capacitor resistor circuit providing a feedback voltage or a feedback current to a second input of the differential circuit based on the feedback frequency;
wherein the differential circuit adjusts its output current based on a difference between the input voltage and the feedback voltage or between the input current and the feedback current;
wherein the differential circuit is adapted to provide the output current to the device having the first CCO as the reference current; and
wherein the feedback frequency is adapted to be substantially equal to a divided version of an output frequency of the device having the first CCO due to the second CCO having substantially matching performance to the first CCO.

2. The circuit of claim 1, wherein the device having the first CCO comprises a digitally controlled oscillator (DCO) or a voltage controlled oscillator (VCO).

3. The circuit of claim 1, wherein the divider circuit is selected such that the feedback frequency equals the reference frequency when the input voltage equals the feedback voltage or the input current equals the feedback current.

4. The circuit of claim 1, wherein the second CCO is adapted to have substantially a same structure as the first CCO.

5. The circuit of claim 1, wherein the differential circuit comprises a differential amplifier and a voltage-to-current converter connected to an output of the differential amplifier.

6. The circuit of claim 1, wherein the reference circuit comprises a reference switched capacitor resistor circuit.

7. The circuit of claim 6, wherein the input voltage provided to the first input of the differential circuit is a reference voltage;
wherein the reference circuit further comprises a differential amplifier and a voltage-to-current converter connected to an output of the differential amplifier;
wherein the reference voltage is provided to a first input of the differential amplifier;
wherein the reference frequency and a first current from the voltage-to-current converter are input to the reference switched capacitor resistor circuit to generate a first voltage provided to a second input of the differential amplifier;
wherein the first current from the voltage-to-current converter is mirrored to the feedback loop circuit to provide a second current; and
wherein the second current and the feedback frequency are input to the feedback switched capacitor resistor circuit to generate the feedback voltage provided to the differential circuit.

8. The circuit of claim 6, wherein the reference frequency and a first current are input to the reference switched capacitor resistor circuit to generate the input voltage provided to the first input of the differential circuit; and
wherein the feedback frequency and a second current equal to the first current are input to the feedback switched capacitor resistor circuit to generate the feedback voltage provided to the second input of the differential circuit.

9. The circuit of claim 6, wherein the reference circuit further comprises a first differential amplifier and a first voltage-to-current converter connected to an output of the first differential amplifier;
wherein a reference voltage is provided to a first input of the first differential amplifier;
wherein the reference frequency and a first current from the first voltage-to-current converter are input to the reference switched capacitor resistor circuit to generate a first voltage provided to a second input of the first differential amplifier;
wherein the first current from the first voltage-to-current converter is the input current provided to the first input of the differential circuit;
wherein the feedback loop circuit further comprises a second differential amplifier and a second voltage-to-current converter connected to an output of the second differential amplifier;
wherein the reference voltage is provided to a first input of the second differential amplifier;
wherein a second current from the second voltage-to-current converter is input to the feedback switched capacitor resistor circuit to generate a second voltage provided to a second input of the second differential amplifier; and
wherein the second current from the second voltage-to-current converter is the feedback current to the second input of the differential circuit.

10. A method of providing a reference current to a device having a first current controlled oscillator (CCO), the method comprising:
providing, by a reference circuit to a first input of a differential circuit of a feedback loop circuit, an input voltage or an input current based on a reference frequency;
providing, by the differential circuit, an output current;
receiving, by a second CCO, the output current from the differential circuit, the second CCO adapted to have substantially matching performance to the first CCO;
producing, by the second CCO, an output frequency in response to the received output current;
dividing, by a divider circuit, the output frequency into a feedback frequency;
providing, by a feedback switched capacitor resistor circuit, a feedback voltage or a feedback current to a second input of the differential circuit based on the feedback frequency;
adjusting, by the differential circuit, its output current based on a difference between the input voltage and the feedback voltage or between the input current and the feedback current; and
providing, by the differential circuit, the output current to the device having the first CCO as the reference current;
wherein the feedback frequency is adapted to be substantially equal to a divided version of an output frequency of the device having the first CCO due to the second CCO having substantially matching performance to the first CCO.

11. The method of claim 10, wherein the device having the first CCO comprises a digitally controlled oscillator (DCO) or a voltage controlled oscillator (VCO).

12. The method of claim 10, wherein the divider circuit is selected such that the feedback frequency equals the reference frequency when the input voltage equals the feedback voltage or the input current equals the feedback current.

13. The method of claim 10, wherein the second CCO is adapted to have substantially a same structure as the first CCO.

14. The method of claim 10, wherein the differential circuit comprises a differential amplifier and a voltage-to-current converter connected to an output of the differential amplifier.

15. The method of claim 10, wherein the reference circuit comprises a reference switched capacitor resistor circuit.

16. The method of claim 15, wherein the input voltage provided to the first input of the differential circuit is a reference voltage;
wherein the method further comprises:
providing the reference voltage to a first input of a differential amplifier of the reference circuit;
providing the reference frequency and a first current from a voltage-to-current converter connected to an output of the differential amplifier to the reference switched capacitor resistor circuit to generate a first voltage;
providing the first voltage to a second input of the differential amplifier;
mirroring the first current from the voltage-to-current converter to the feedback loop circuit to provide a second current; and
providing the second current and the feedback frequency to the feedback switched capacitor resistor circuit to generate the feedback voltage provided to the differential circuit.

17. The method of claim 15, further comprising:
providing the reference frequency and a first current to the reference switched capacitor resistor circuit to generate the input voltage provided to the first input of the differential circuit; and
providing the feedback frequency and a second current equal to the first current to the feedback switched capacitor resistor circuit to generate the feedback voltage provided to the second input of the differential circuit.

18. The method of claim 15, further comprising:
providing a reference voltage to a first input of a first differential amplifier of the reference circuit;
providing the reference frequency and a first current from a first voltage-to-current converter connected to an output of the first differential amplifier to the reference switched capacitor resistor circuit to generate a first voltage;
providing the first voltage to a second input of the first differential amplifier;
providing the reference voltage to a first input of a second differential amplifier of the feedback loop circuit;
providing a second current from a second voltage-to-current converter connected to an output of the second differential amplifier to the feedback switched capacitor resistor circuit to generate a second voltage; and
providing the second voltage to a second input of the second differential amplifier;
wherein the first current from the first voltage-to-current converter is the input current provided to the first input of the differential circuit; and
wherein the second current from the second voltage-to-current converter is the feedback current to the second input of the differential circuit.

19-32. (canceled)
